(19) United States
(12) Patent Application Publication
(10) Pub. No.: US 2005/0062047 A1
(43) Pub. Date: Mar. 24, 2005

(54) Transistor substrate, display device, and method of manufacturing transistor substrate and display device

(76) Inventors: Ryuji Nishikawa, Gifu-shi (JP); Kazuhiro Imao, Gifu-shi (JP); Ken Wakita, Anpachi-gun (JP); Kiyoshi Yoneda, Mizuho-shi (JP)

Correspondence Address: CANTOR COLBURN, LLP, 55 GRIFFIN ROAD SOUTH, BLOOMFIELD, CT, 06002, US

(21) Appl. No.: 10/945,782

(22) Filed: Sep. 21, 2004

(30) Foreign Application Priority Data
Sep. 22, 2003 (JP) 2003-330123
Jul. 8, 2004 (JP) 2004-201925

(51) Int. Cl. H01L 29/76

(52) U.S. Cl. 257/72

(57) ABSTRACT

A device has a first transistor and a second transistor wherein a channel length direction of the first transistor extends along a first direction and a channel length direction of the second transistor extends along a second direction intersecting the first direction, and the second transistor is formed on a same substrate as the first transistor. A first channel region and a second channel region are formed in semiconductor layers which are simultaneously formed and a mobility of the semiconductor film has an anisotropy in the first and second directions. With this structure, transistors having different mobilities can be obtained while using the semiconductor films formed on the same substrate and from a same material. For example, it is possible to form a transistor in which a high resistance is required using a semiconductor layer of the same characteristics as that in a transistor in which a high speed operation is desired, on the same substrate and with a minimum area.

### CROSS-REFERENCE TO RELATED APPLICATIONS

The priority Japanese Patent Applications, Numbers 2003-330123 and 2004-201925, upon which this patent application is based are hereby incorporated by reference.

### BACKGROUND OF THE INVENTION

1. Field of the Invention

The present invention relates to a transistor substrate and a display device in which a plurality of transistors are used, and methods of manufacturing the transistor substrate and the display device.

2. Description of the Related Art

Recently, electroluminescence (hereinafter simply referred to as “EL”) display devices in which an EL element is used have attracted much attention as new display devices. In particular, active matrix EL display devices having, in each pixel, a switching thin film transistor (S-TFT) for selecting a pixel and a driving thin film transistor (D-TFT) for supplying power for driving the EL element based on an output of the switching transistor have drawn interest for their ability to display a high resolution image.

FIG. 1 is a diagram schematically showing a typical EL display device. A plurality of gate signal lines 151, a plurality of drain (data) signal lines 152, and a plurality of power supply lines 153 are placed and pixels surrounded by these signal lines and power supply lines are formed in a matrix form. An S-TFT 110, a D-TFT 120, and a storage capacitor Sc are provided in each pixel.

FIG. 2 is a plan view showing a pixel in an EL display device of a related art. Two S-TFTs 110 which are connected in series with respect to the drain signal line 152, a storage capacitor electrode line 154, and a portion of a storage capacitor electrode 155 are placed between an emissive region E in which light emission of the EL element is viewed and a gate signal line 151. Gate electrodes 114 of two S-TFTs 110 are connected to the gate signal line 151. A drain region 112d of the S-TFT 110 on a side near the drain signal line 152 is connected to the drain signal line 152. Similarly, a source region 112s of the S-TFT 110 connected to the drain signal line 152 via a channel region 112c is connected to the storage capacitor electrode 155 which forms a capacitor along with the storage capacitor electrode line 154. The source region 112s of the S-TFT 110 is also connected to a gate electrode 124 of the D-TFT 120. A source region 122s of the D-TFT 120 is connected to the power supply line 153 and a drain region 122d of the D-TFT 120 is connected to a pixel electrode 161 of the EL element via a drain electrode 126. The storage capacitor electrode line 154 is formed to oppose a semiconductor layer 112 with an insulating film there between, the semiconductor layer 112 also functioning as the storage capacitor electrode 155 connected to the source region 112s of the S-TFT 110. With this structure, charges are accumulated between the storage capacitor electrode line 154 and the storage capacitor electrode 155 to form the storage capacitor Sc.

FIG. 3 is a cross sectional view along a W-W line of FIG. 2. An insulating film 111 and semiconductor layers 112 and 122 made of polycrystalline silicon layer or microcrystalline silicon layer (non-single crystalline silicon layer) are formed above a substrate 130, and a gate insulating film 113 and gate electrode 114 and 124 are formed above the insulating film 111 and the semiconductor layers 112 and 122. In the semiconductor layer 122, a drain region 122d, a source region 122s, and a channel region 122c provided between the drain region 122d and the source region 122s and having a channel length of Ld₀ are formed. An interlayer insulating film 115 is formed over the almost entire substrate, including the gate electrodes 114 and 124 and contact holes are formed through the interlayer insulating film 115 at positions corresponding to the source region 122s and the drain region 122d. A drain electrode 126 made of a metal and a source electrode 127 connected to the drive power supply line 153 are placed filling these contact holes. A planarizing film 117 for planarizing the surface is layered above the interlayer insulating film 115, the planarizing film 177 being made of an organic resin and having contact holes formed therethrough at a position corresponding to the drain electrode. A pixel electrode 161 is connected to the drain electrode 126 through the contact hole and a light emitting element layer 165, which includes three layers of a hole transport layer 162, an emissive layer 163, and an electron transport layer 164, and an opposing electrode 166 are formed in this order above the pixel electrode 161. A second planarizing film 167 made of an insulating resin is layered and formed between the hole transport layer 162 and the pixel electrode 161. A region in which the pixel electrode 161 is exposed is defined by an opening formed through the second planarizing film 167 and above the pixel electrode 161.

In the EL display device of the related art described above, an S-TFT and a D-TFT, which are different types of TFTs having different functionalities, are required. In a transistor substrate or a display device which requires two or more types of TFTs such as the described structure, the required characteristics of the TFTs such as, for example, current supply capability differ from each other.

However, when the semiconductor layers of the TFTs in the related art are uniformly crystallized, the non-single crystalline silicon which can be obtained would have approximately equal average grain size, that is, approximately equal mobility. When the TFT size (channel width and/or channel length) is set to be common for these TFTs using such non-single crystalline silicon, the mobility in all TFTs would be the same. Therefore, in order to form a plurality of TFTs having different characteristics, for example, it is necessary to intentionally reduce the drive capability in one TFT compared to the other TFT by significantly elongating the channel length in this TFT or to increase the TFT size of a TFT to increase the drive capability of the TFT compared to the other TFT. Because of this, the size of TFT is unnecessarily increased and the space is not efficiently used.

Moreover, a current driven light emitting element such as an EL element has a tendency to be degraded as current flows. Therefore, it is not desirable to direct a current in an amount greater than the minimum required from the viewpoint of extending the lifetime of such a light emitting element. In consideration of this, as shown in FIG. 2, it is necessary to limit the current flowing through the D-TFT 120 by setting the channel length Ld₀ of the D-TFT 120 to be significantly longer than the channel length of the S-TFT 110 in order to supply a current of minimum required amount to the EL element. However, when the channel length Ld₀ of the D-TFT 120 is elongated, the usage efficiency of the space is reduced, and, in a display device which requires that the components such as the TFT be placed within a limited space, a percentage of area which can be used as a viewable region within the display region, that is, an aperture ratio, is reduced, resulting in reduction in the brightness, transmissivity, or both.

### SUMMARY OF THE INVENTION

The present invention advantageously simplifies the formation of transistors having different characteristics satisfying different requirements.

According to one aspect of the present invention, there is provided a semiconductor device comprising a first transistor having a first channel region in which a channel length direction extends along a first direction, and a second transistor formed on a same substrate as the first transistor and having a second channel region in which a channel length direction extends along a second direction which intersects the first direction, wherein the first channel region and second channel region are formed in semiconductor layers which are simultaneously formed, and a mobility along the first direction and a mobility along the second direction differ from each other in the semiconductor layers.

According to another aspect of the present invention, there is provided a semiconductor device wherein a first channel region and a second channel region of a first transistor and a second transistor are formed in semiconductor layers which are simultaneously formed, and a grain boundary density along a first direction and a grain boundary density along a second direction differ from each other in the semiconductor layers.

According to another aspect of the present invention, there is provided a semiconductor device wherein a first channel region and a second channel region of a first transistor and a second transistor are formed in semiconductor layers which are simultaneously formed, and an average crystal length along a first direction and an average crystal length along a second direction differ from each other in the semiconductor layers.

According to another aspect of the present invention, there is provided a display device comprising at least one pixel wherein each pixel comprises a display element, a first transistor having a first channel region in which a channel length direction extends along a first direction and a second transistor having a second channel region in which a channel length direction extends along a second direction which intersects the first direction, the first channel region and the second channel region are formed in semiconductor layers which are simultaneously formed, and a mobility along the first direction and a mobility along the second direction differ from each other in the semiconductor layers.

According to another aspect of the present invention, there is provided a display device wherein a first channel region and a second channel region of a first transistor and a second transistor are formed in semiconductor layers which are simultaneously formed, and a grain boundary density along a first direction is smaller than a grain boundary density along a second direction in the semiconductor layers.

According to another aspect of the present invention, there is provided a display device wherein a first channel region and a second channel region of a first transistor and a second transistor are formed in semiconductor layers which are simultaneously formed, and an average crystal length along a first direction is longer than an average crystal length along a second direction in the semiconductor layers.

According to another aspect of the present invention, there is provided a semiconductor device comprising a first transistor and a second transistor on a same substrate, wherein a common insulating film is formed over a first channel region and a second channel region, a cap film is provided between the insulating film and a channel region of the second transistor, and a crystal grain size of a semiconductor layer forming a channel region of the first transistor and a crystal grain size of a semiconductor layer forming the channel region of the second transistor differ from each other.

According to another aspect of the present invention, there is provided a display device comprising at least one pixel, wherein each pixel comprises at least a pixel electrode, a first transistor, and a second transistor, one of two conductive regions of the first transistor is connected to a control electrode of the second transistor, the second transistor supplies a signal corresponding to an output of the first transistor to the pixel electrode, a channel region of the first transistor and a channel region of the second transistor are formed using a same semiconductor material, a common insulating film is formed over a first channel region and a second channel region, a cap film is provided between the insulating film and the channel region of the second transistor, and a crystal grain size in a semiconductor layer forming a channel region of the first transistor and a crystal grain size of the semiconductor layer forming the channel region of the second transistor differ from each other.

According to another aspect of the present invention, there is provided a method of manufacturing a display device or a semiconductor device comprising at least a first transistor and a second transistor, comprising the steps of forming an amorphous silicon film above a substrate, forming a cap film covering a channel formation region of the second transistor above the amorphous silicon film, and crystallizing the amorphous silicon film by applying a laser annealing process to the amorphous silicon film while the channel formation region of the second transistor is covered with the cap film and a surface of the amorphous silicon film is exposed in a channel formation region of the first transistor.

According to the present invention, by using, as the semiconductor layers of the first and second transistors, semiconductor layers in a crystalline state with a same anisotropy in mobility, it is possible to form first and second transistors having different mobilities on a same substrate while using semiconductor layers which can be simultaneously obtained using a same material (for example, obtained in a same annealing step for crystallization). Therefore, it is possible to form, for example, a transistor in which a high resistance is required and a transistor in which a high speed operation is required using semiconductor layers having same characteristics.

In addition, by selectively forming, for example, the channel length direction of the transistor in which a high resistance is required along a direction of the semiconductor layer with a low mobility, it is possible to form the transistor with a minimum area.

Because of this, a semiconductor device or display device with a high degree of integration can be obtained and it is possible to facilitate further reduction of the size of the device and further increase in the resolution.

Moreover, when a plurality of transistors are to be formed in one pixel in a display device, it is no longer necessary to employ significantly differing sizes for the transistors, allowing for effective usage of the pixel region and a higher resolution. In addition, because the transistors can be effectively placed, a display area within one pixel region can be increased, and, therefore, the aperture ratio can be improved.

By selectively forming a cap film above a channel region of a second transistor as in the present invention, it is possible to obtain different sizes for grain sizes of non-single crystalline silicon in the channel regions of the first and second transistors by merely simultaneously applying an annealing process to the semiconductor layers of the first and second transistors for crystallization.

By leaving the cap film in the completed transistor, it is possible to vary, between the first and second transistors, a thickness of an insulating film between the channel region and the gate electrode, and thus, it is possible to intentionally vary the current supply capability in the two transistors. Thus, even when a plurality of transistors having different current supply capability requirements are to be formed on the same substrate, it is not necessary to significantly vary the size of the transistors, which allows for effective usage of the space. Therefore, it is possible to further increase the degree of integration, reduce the size of the device, increase the resolution, and realize other beneficial effects.

### BRIEF DESCRIPTION OF THE DRAWINGS

Preferred embodiments of the present invention will be described in detail based on the following figures, wherein:

FIG. 1 is a diagram schematically showing a structure of a typical EL display device;

FIG. 2 is a diagram schematically showing a pixel region of an EL display device according to a related art;

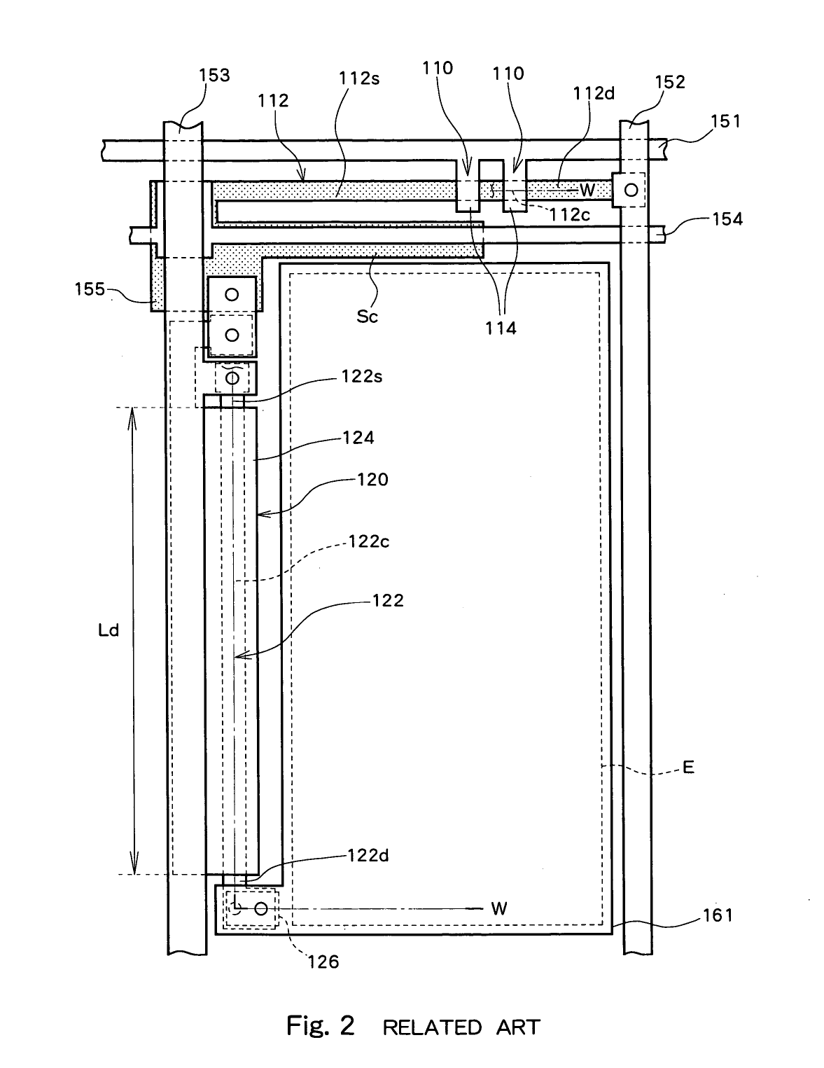

FIG. 3 is a diagram showing a W-W cross section of FIG. 2;

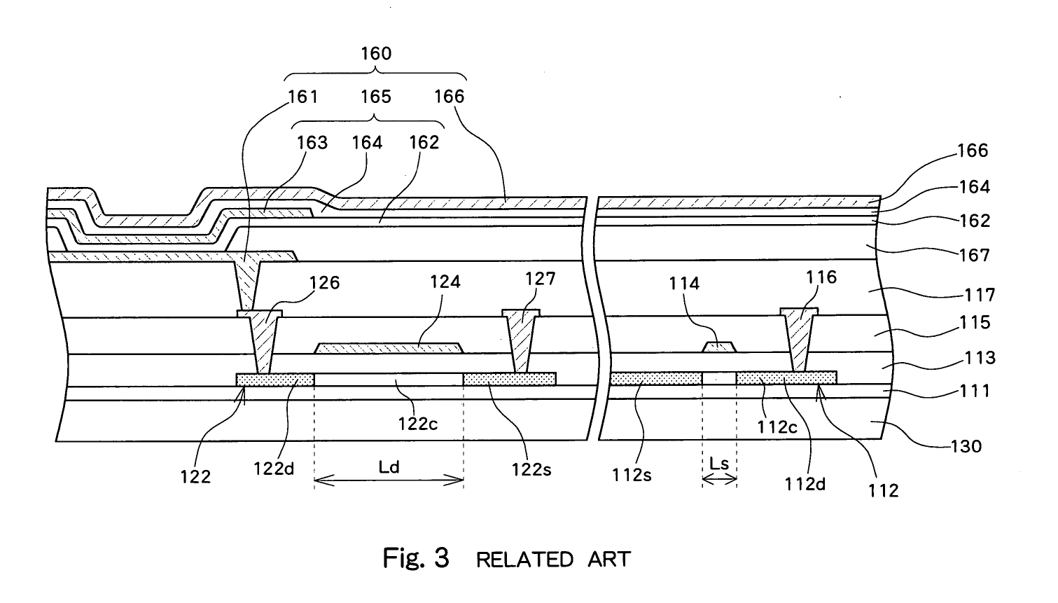

FIG. 4 is a diagram showing a pixel region of an EL display device according to a first preferred embodiment of the present invention;

FIG. 5 is a diagram for explaining an anisotropy of mobility in a semiconductor layer according to a preferred embodiment of the present invention;

FIGS. 6A and 6B are diagrams schematically showing a cross sectional structure along an X-X line and a Y-Y line of FIG. 4, respectively;

FIG. 7 is a diagram showing a pixel region of an EL display device according to a second preferred embodiment of the present invention;

FIG. 8 is a diagram showing a pixel region of an EL display device according to a third preferred embodiment of the present invention;

FIG. 9 is a diagram showing a pixel region of an EL display device according to a fourth preferred embodiment of the present invention;

FIG. 10 is a diagram schematically showing a cross section along a Z-Z line in FIG. 9;

FIGS. 11A, 11B, 11C, 11D, and 11E are diagrams showing manufacturing steps of a display device according to a fourth preferred embodiment of the present invention, at positions along the Z-Z line of FIG. 10;

FIG. 12 is a diagram showing a relationship between a crystallization energy intensity and a crystal grain size due to the presence or absence of a cap film according to a preferred embodiment of the present invention;

FIG. 13 is a diagram showing a relationship between a crystallization energy intensity and a crystal grain size due to a thickness of a cap film according to a preferred embodiment of the present invention; and

FIG. 14 is a diagram showing a pixel region of an EL display device according to a fifth preferred embodiment of the present invention.

### DESCRIPTION OF PREFERRED EMBODIMENTS

Preferred embodiments (hereinafter referred to simply as “embodiments”) of the present invention will now be described.

### First Embodiment

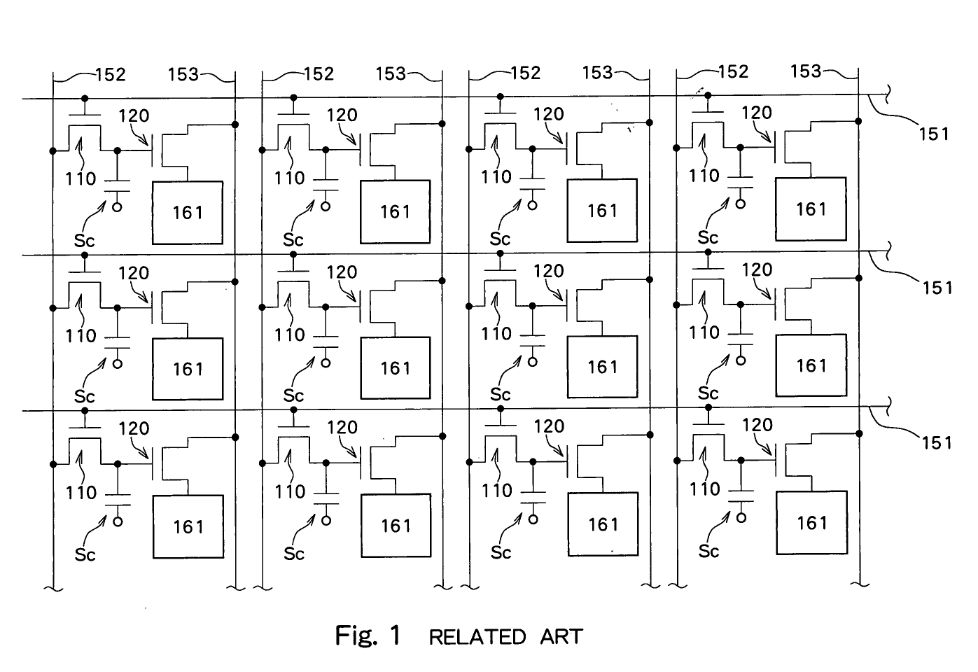

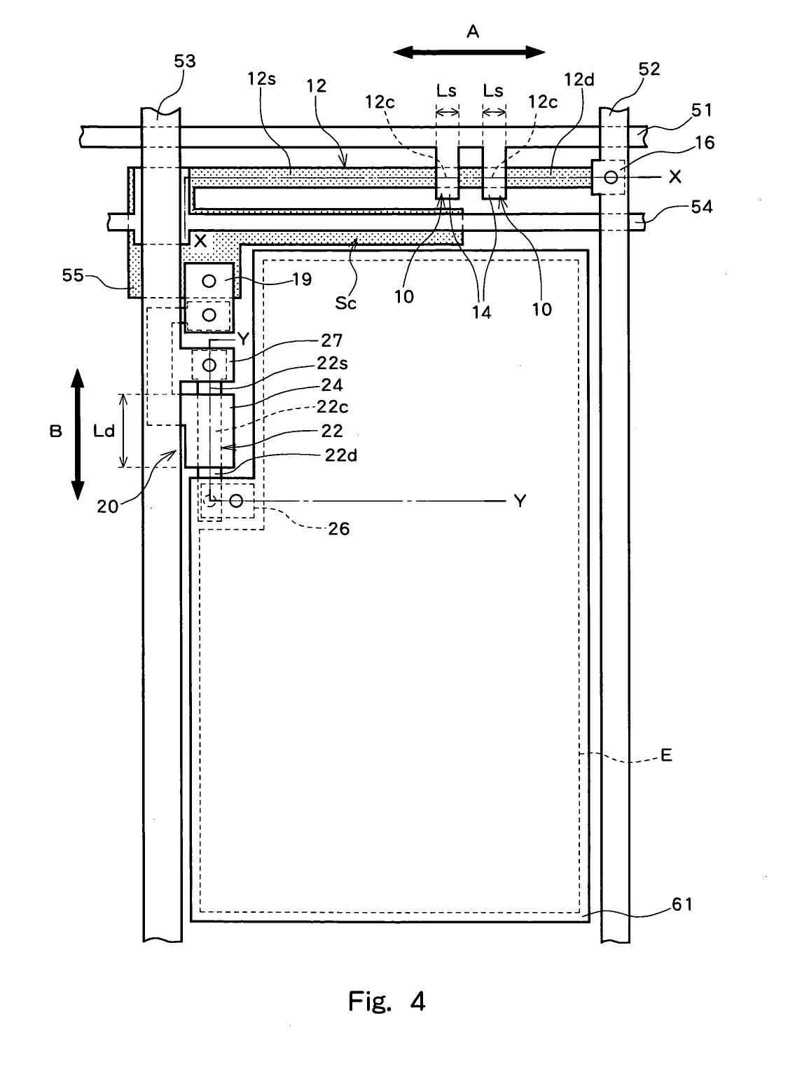

FIG. 4 is a diagram showing a pixel in an EL display device according to a first preferred embodiment of the present invention. A planar structure of a pixel in the EL display device will now be conceptually described referring to FIG. 4. The overall circuit structure of the EL display device is common to that shown in FIG. 1.

A plurality of gate signal lines 51 are placed along a horizontal direction and a plurality of drain (data) signal lines 52 and a plurality of power supply lines 53 are placed along a vertical direction. Two S-TFTs 10 connected in series with respect to a corresponding one of the drain signal lines 52, a storage capacitor electrode line 54, and a portion of a storage capacitor electrode 55 are placed between an emissive region E in which light emission of the EL element is viewed and the gate signal line 51.

Gate electrodes 14 of two S-TFTs 10 which are switching elements are connected to the gate signal line 51. More specifically, two gate electrodes 14 extend in parallel along a column direction from the gate signal line 51 to form a double gate structure. A channel region 12c is formed in a partial region of a semiconductor layer 12 covered by the gate electrode 14 (region overlapping the gate electrode 14), and a source region 12s and a drain region 12d are placed sandwiching the channel region 12c. Therefore, in the S-TFT 10, an “A” direction shown in FIG. 4 (a row direction or horizontal scan direction) is the conductive direction (carrier moving direction) and the length of the channel region 12c along the A direction is the channel length Ls. A source region 12s closer to the drain signal line 52 is connected to the drain signal line 52 through a drain electrode 16. A source region 12s of the S-TFT 10 connected to the drain signal line 52 through the channel region 12c is connected to the storage capacitor electrode 55 and is also connected, through a contact pad 19, to a gate electrode 24 of a D-TFT 20 which is a driver element.

In the semiconductor 22 forming the active layer of the D-TFT 20, a region covered by a gate electrode 24 forms a channel region 22c and a source region 22s and a drain region 22d are placed sandwiching the channel region 22c. In other words, in the D-TFT 20,the “B” direction shown in FIG. 4 (a column direction or vertical scan direction) is the conductive direction (carrier moving direction) and a length of the channel region 22c along the B direction is the channel length Ld. The source region 22s is connected to the power supply line 53 through a source electrode 27 and the drain region 22d is connected to a pixel electrode 61 of an organic EL element through a drain electrode 26.

The storage capacitor electrode line 54 is formed to oppose the semiconductor layer 12 which also functions as the storage capacitor electrode 55 connected to the source region 12s of the S-TFT 10, with a gate insulating film 13 therebetween. With this structure, charges are accumulated between the storage capacitor electrode line 54 and the storage capacitor electrode 55 to form a capacitor. This capacitor forms a storage capacitor Sc for storing a voltage applied to the gate electrode 24 of the D-TFT 20.

In the first embodiment, by using a material (semiconductor material) having an anisotropy in mobility for the active layers of the transistors and placing the carrier moving directions of a plurality of transistors to be directed in different conductive directions of the anisotropic material layer, transistors having different mobilities are obtained while using semiconductor layers of the same layer which are formed simultaneously and through same formation steps and have approximately identical characteristics.

As the material having an anisotropy in mobility, p-Si in which the crystals are selectively grown in a specific direction of a film plane (for example, a lateral or row direction) may be considered. Such p-Si will now be described.

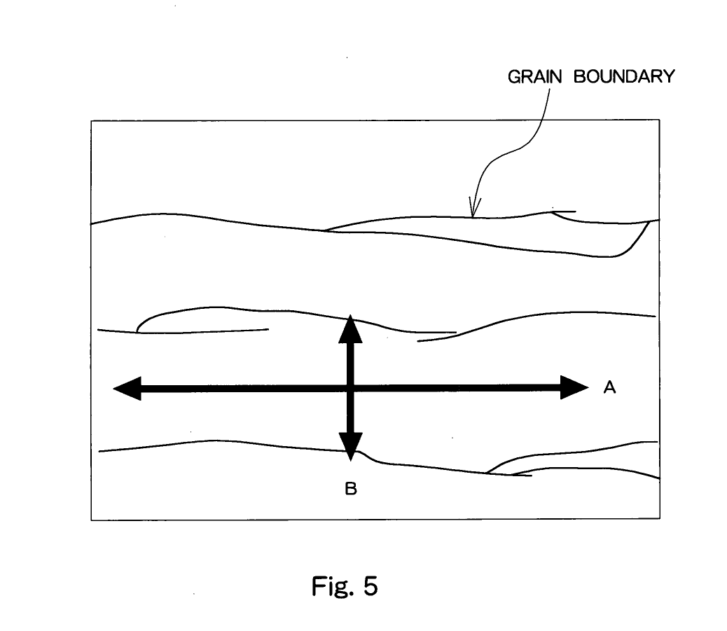

FIG. 5 is a diagram schematically showing a crystallization state of p-Si which forms the active layers of the first TFT 10 and the second TFT 20. The line shown in FIG. 5 shows an interface between crystals, that is, a grain boundary. It can be seen that, because each crystal grain has a directionality in that the crystal grain is longer along the A direction and shorter along the B direction, the p-Si is a lateral direction grown crystal having an anisotropy in the direction of growth. As shown in the figure, the A direction, which is the conductive direction (channel length direction) of the S-TFT 10, is set to a longitudinal direction of the crystal, that is, a direction in which a number of passed grain boundaries (number of grain boundaries)is small, that is, a direction of a low grain boundary density. On the other hand, the B direction, which is the conductive direction (channel length direction) of the D-TFT 20, is set to a lateral direction of the crystal, that is, a direction in which the number of grain boundaries is large (that is, a direction of a high grain boundary density). In the first embodiment, the A direction is perpendicular to the B direction.

As the number of grain boundaries increases, that is, as the grain boundary density increases, the mobility p of the TFT decreases. Therefore, by intentionally setting the number of grain boundaries in the B direction to be larger than the number of grain-boundaries in the A direction, it is possible to set a mobility Pd of the second TFT 20 having the conductive direction along the B direction to be smaller than the mobility ps of the first TFT 10 having the conductive direction along the A direction. Even when the channel length Ls of the S-TFT is equal to the channel length Ld of the D-TFT (that is, Ls=Ld), a relationship of μs>μd can still be obtained as long as the channel widths of the TFTs do not significantly differ from each other. Situations may exist in which the number of passed grain boundaries in the conductive direction of the semiconductor layer 12 may differ for a plurality of first TFTs 10 formed in the same conductive direction. In such a case, an average of the number of grain boundaries is calculated and set to be smaller than the number of grain boundaries of the second TFT 20 (when there are a plurality of second TFT substrates, an average of the numbers of the grain boundaries). In this process, in order to reduce the overall variation in manufacture of the transistors including the semiconductor layer, it is desirable to place the same type of TFTs along the same conductive direction.

In general, the relationship between a current I flowing through the TFT, a mobility μ along the conductive direction of the semiconductor layer of the TFT, a channel width W of the TFT, and a channel length L of the TFT can be represented by the following equation (1).
I ∝ μ·W/L (1)

From this relationship, it can be seen that, in order to flow a current of the same value as that of the TFT of the related art through the second TFT 20, the channel length Ld of the second TFT may be changed by an amount corresponding to a change of the mobility from μ₀ in the TFT of the related art to μₛ (μₛ/μ₀) (Ld=Ld₀·μₛ/μ₀). In other words, by using a lateral direction grown crystal as shown in FIG. 5 and placing the B direction in a direction of a smaller mobility to achieve a relationship of μₛ<μ₀, it is possible to shorten the channel length Ld.

As a method of forming p-Si grown in the lateral direction used as the semiconductor layer of the transistor in the present invention, the following methods can be considered.

(i) CLC (CW-Laser Lateral Crystallization)

CLC is a method in which a crystal is grown along a scan direction of laser by irradiating amorphous silicon with DPSS (Diode-Pumped Solid State) laser and annealing for crystallization. In this method, the crystal length along the scan direction can be elongated, that is, the crystal grain size can be increased, by controlling the rate of laser scan.

(ii) SELAX (Selectively Enlarging Laser X'tallization)

SELAX is a crystallization annealing method in which polycrystalline silicon with a small grain size is formed by irradiating amorphous silicon with an excimer laser, and then the polycrystalline silicon is irradiated with a solid-state pulse laser to form polycrystalline silicon having the scan direction of the solid-state pulse laser as the longitudinal direction of the crystal grain.

(iii) SLS (Sequential Lateral Solidification)

SLS is a method in which amorphous silicon is irradiated with a line-shaped excimer laser, a crystal elongated in a direction of both short sides of the laser (scan direction of laser) is grown, and crystal is continuously formed by overlapping a portion of the crystal and a portion of the crystal to be grown when the next shot of laser irradiation is applied. In methods (i) and (ii), a low-power solid-state laser is used whereas in SLS, an excimer laser having a higher power than the solid-state laser is irradiated, and thus, is effective.

With any of the methods described above, it is possible to execute an annealing process for polycrystallization and to obtain a semiconductor layer having anisotropy in the mobility by uniformly irradiating the entire surface of the substrate with laser. The first TFT 10 is placed such that a direction in which the number of grain boundaries is small is parallel to the A direction which is the conductive direction of the first TFT 10 and the second TFT 20 is placed so that the B direction which is the conductive direction of the second TFT 20 is perpendicular to the A direction. In this manner, it is possible to obtain an EL display device having transistors with different mobilities while the transistors use semiconductor layers obtained using the same material and through at least the same laser annealing step. In a more preferable configuration, the A direction is placed along a direction in which the density of the grain boundaries is minimum, and the B direction is placed along a direction in which the density of the grain boundaries is maximum. According to this configuration, it is possible to maximize the mobility of the S-TFT 10 which is the transistor in which a high mobility is required and to minimize the mobility of the D-TFT 20 which is the transistor in which a low mobility is sufficient. As a consequence, it is possible to form the S-TFT 10 and the D-TFT 20 with minimum transistor sizes.

In the present embodiment, by using the SLS described above, TFTs can be formed with a mobility of 100 cm²/Vs-250 cm²/Vs when the TFT is placed along the A direction and with a mobility of 40 cm 2/Vs-80 cm²/Vs when the TFT is placed along the B direction, while the TFTs of the related art have a mobility of 90 cm²/Vs-100 cm²/Vs. In other words, it is possible to achieve a relationship of μs=(approximately 2.5-6)×μ_{d}. The relationship between channel lengths of the S-TFT and D-TFT in the device of related art has been Ld₀=(approximately 3-4)×Ls₀, and therefore, the relationship between currents Is₀ and Id₀ flowing through the S-TFT and D-TFT of the related art is Id₀=(approximately ¼-⅓)×Is₀, from the above-described equation (1). Therefore, when an S-TFT and a D-TFT having current supply capabilities which are equivalent to those in the related art are to be formed, if the S-TFT is formed in a transistor size which is identical to that in the related art, the D-TFT can be formed with a channel length which is approximately ⅙-1/2.5 of that in the related art. Therefore, the region occupied by the D-TFT can be reduced to approximately ⅙-1/2.5 which allows the difference to be used as the light emitting region, and consequently, a greater aperture ratio.

The present invention is not limited to a configuration as described above regarding the first preferred embodiment of the present invention. For example, in the first preferred embodiment or in the other preferred embodiments, the A direction and the B direction need not perpendicularly intersect each other, or the relationship between the mobility of the TFT along the A direction and the mobility of the TFT along the B direction may be opposite to that described above. That is, the A direction and the B direction need only be different. In addition, as a standard for placing the A direction, it is possible to use a length of crystal (crystal grain size) instead of the grain boundary density. As described, the longitudinal direction of crystal grains has a directionality in the semiconductor layer as a whole, but the length of the crystal differs for each crystal grain. In this case, by placing the TFTs such that the average length of the crystal (average crystal length) along the A direction is longer than the average crystal length along the B direction, it is possible to obtain an EL display device similar to that in the first preferred embodiment. In this case also, the relationship between the average crystal lengths in different directions is not limited to that described above in the description of the first preferred embodiment.

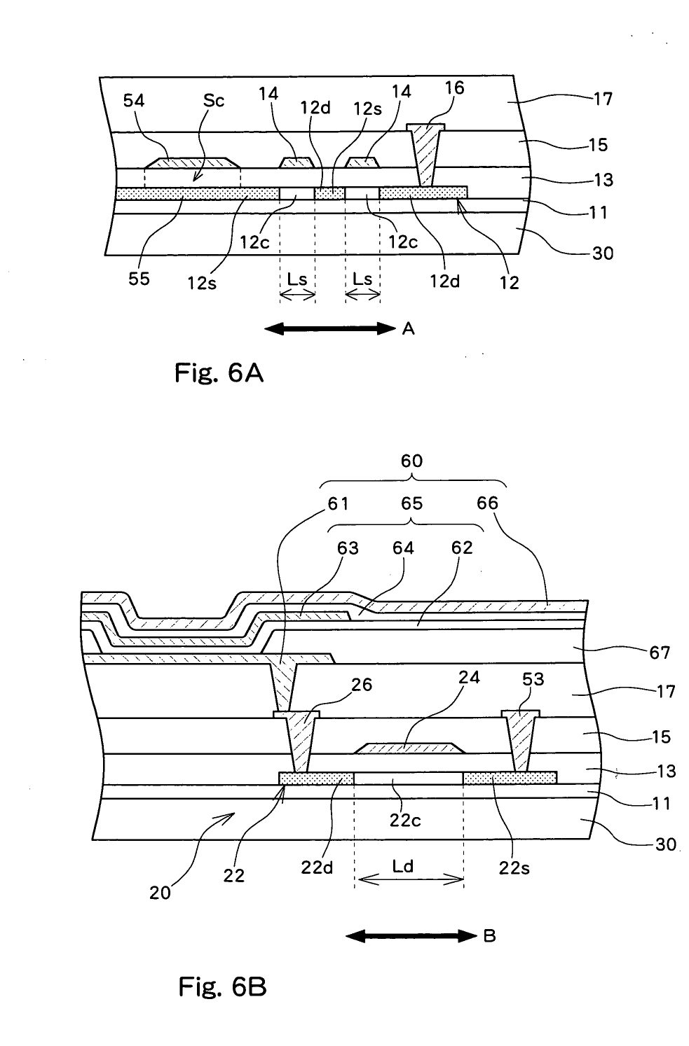

FIG. 6A is a cross sectional view along the X-X line of FIG. 4 and shows a structure of the S-TFT 10 which is a top-gate TFT for switching and a storage capacitor Sc connected to the source region 12s of the S-TFT 10. The cross sectional structure will now be described referring to FIG. 6A.

An insulating film 11 which is made of, for example, a SiN film and a SiO₂ film is layered on a substrate 30. A semiconductor layer 12 made of a p-Si layer which is laterally grown through a method such as that described above is formed on the insulating film 11 and connected to the storage capacitor electrode 55 made of the same p-Si layer. In the semiconductor layer 12, a drain region 12d, a source region 12s, and a channel region 12c provided between the drain region 12d and the source region 12s and having a channel length Ls are formed. A gate insulating film 13 made of a SiO₂ film and a SiN film is layered covering the semiconductor layer 12 and the storage capacitor electrode 55. A gate electrode 14 and a storage capacitor electrode line 54 each of which is made of a refractory metal such as chromium (Cr) and molybdenum (Mo) are formed above the gate insulating film 13. The gate electrode 14 is provided to pass over the channel region 12c and the storage capacitor electrode line 54 is provided to oppose the storage capacitor electrode 55. An interlayer insulating film 15 made of a SiO₂ film, a SiN film, and a SiO₂ film is formed over the entire surface of the gate electrode 14 and the gate insulating film 13. A drain electrode 16 made of a metal such as Al is provided through a contact hole formed through the interlayer insulating film 15 at a position corresponding to the drain region 12d and a planarizing film 17 made of an organic resin for planarizing the surface is formed over the entire surface.

FIG. 6B is a cross sectional view along the Y-Y line of FIG. 4 and shows a structure of the TFT 20 which is a top-gate TFT for driving an organic EL element. The cross sectional structure of the TFT 20 will now be described in more detail referring to FIG. 6B.

An insulating film 11 made of, for example, a SiN film and a SiO₂ film is layered on a substrate 30. A semiconductor layer 22 made of the p-Si film in the same layer as the semiconductor layer 12 of the S-TFT 10 is formed on the insulating film 11. In the semiconductor layer 22, a drain region 22d and a source region 22s which are two conductive regions of the D-TFT 20 are formed and a channel region 22c having a channel length Ld is formed between the drain region 22d and the source region 22s. A gate insulating film 13 made of a SiO₂ film and a SiN film is layered covering the semiconductor layer 22. A gate electrode 24 made of a refractory metal such as Cr and Mo is formed on the gate insulating film 13, covering the formation region of the channel region 22c and passing over the semiconductor layer 22 extending along the power supply line 53. An interlayer insulating film 15 having a layered structure of a SiO₂ film, a SiN film, and a SiO₂ film is formed over the entire surface of the gate electrode 24 and the gate insulating film 13. A drain electrode 26 made of a metal and a source electrode 27 which is formed, in the exemplified structure, protruding from the drive power supply line 53 and integral with the power supply line 53 are placed through contact holes formed through the interlayer insulating film 15 at positions corresponding to the source region 22s and the drain region 22d. A planarizing film 17 made of an organic resin for planarizing a surface is layered over the drain electrode 26, the source electrode, and the interlayer insulating film 15. A pixel electrode 61 formed above the planarizing film 17 and made of a transparent material such as ITO (Indium Tin Oxide) is connected to the drain electrode 26 through a contact hole formed through the planarizing film 17. The pixel electrode 61 is formed in an individual pattern for each pixel. A light emitting element layer 65 having, for example, a three-layer structure of a hole transport layer 62, an emissive layer 63, and an electron transport layer 64 is layered and formed on the pixel electrode 61. An opposing electrode 66 made of an aluminum alloy or the like is formed common to the pixels and covering the light emitting element layer 65. The layers from the pixel electrode 61 to the opposing electrode 66 together form an EL element 60. A second planarizing film 67 made of an insulating resin is layered and formed between the hole transport layer 62 and the pixel electrode 61 covering the edges of the pixel electrode 61. The pixel electrode 61 is exposed by an opening formed through the second planarizing film 67 and above the pixel electrode 61 so that the pixel electrode 61 directly contacts the light emitting element layer 65 to define a region which forms the emissive region E. In other words, the emissive region E of FIG. 1 is defined by an opening through the second planarizing film 67.

### Second Embodiment

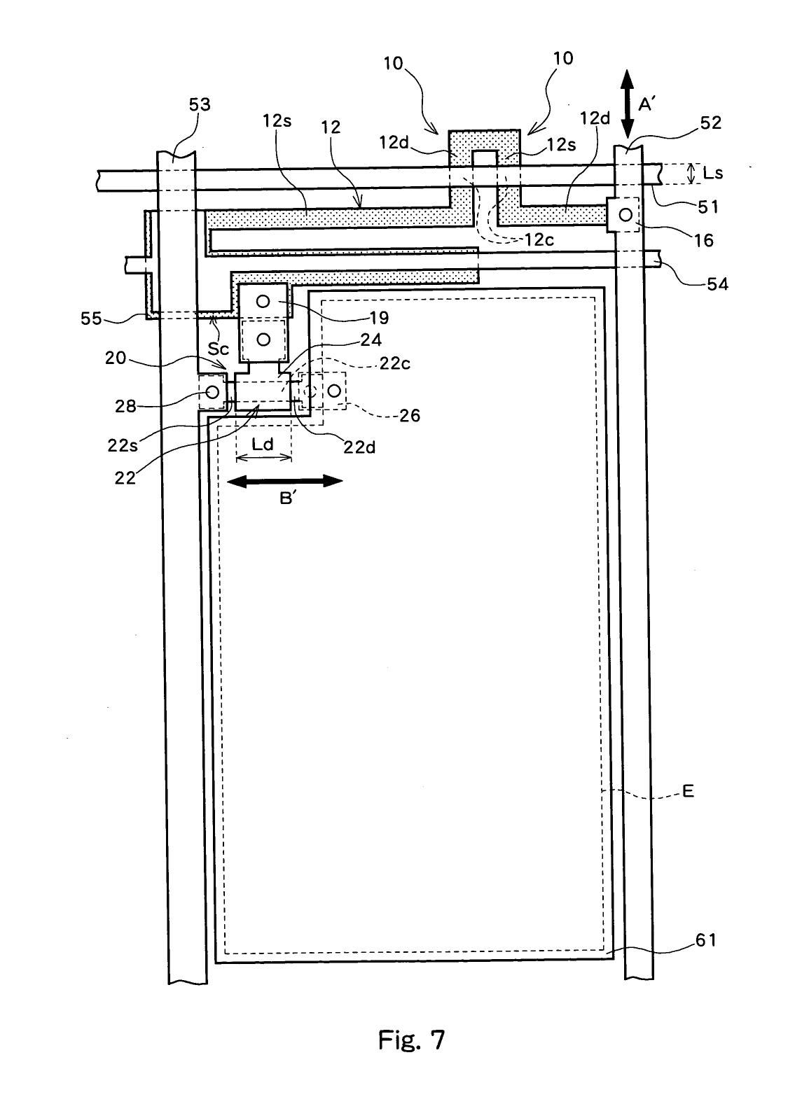

An EL display device according to a second preferred embodiment of the present invention will now be described. FIG. 7 is a plan view showing a pixel of an EL display device according to the second preferred embodiment. Layers and structures identical to those shown on FIG. 4 are assigned the same reference numerals as those in FIG. 4 and will not be described again.

A portion of the gate signal line 51 is used as a gate electrode 14 and a channel region 12c is formed by forming a part of the semiconductor layer 12 in a “U” shape to form a region overlapping the gate electrode 14. This configuration also differs from that shown in FIG. 4 in that the channel length direction of the semiconductor layer 22 of the D-TFT 20 is different by 90° and is directed along a row direction which is an extension direction of the gate signal line 51. Thus, in the second embodiment, the conductive directions A′ and B′ which are channel length directions, that is, carrier moving directions, of the S-TFT 10 and the D-TFT 20 have a relationship opposite to that between the A and B directions described above. This relationship can be changed to a relationship similar to that between the A and B directions in FIG. 4 by changing the scan direction of laser or the like for crystallizing the semiconductor layer. More specifically, this is achieved by, for example, scanning along the A′ direction with line-shaped laser such that the carrier mobility along the A′ direction is greater than the carrier mobility along the B′ direction in FIG. 7.

### Third Embodiment

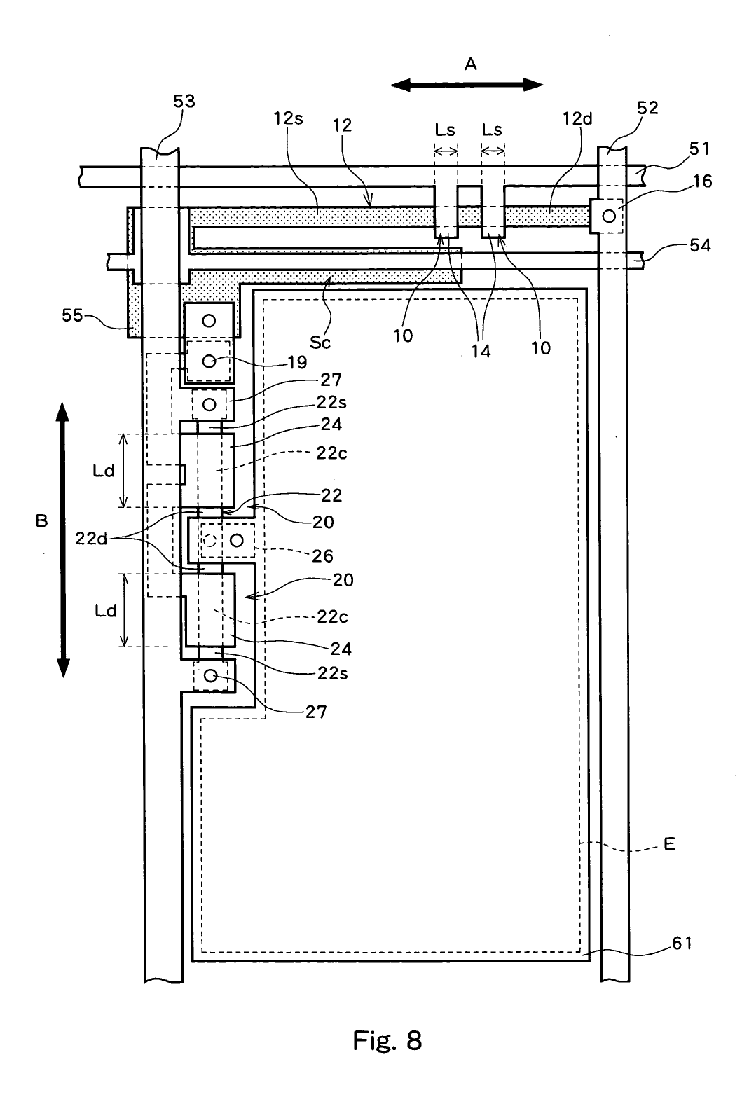

An EL display device according to a third preferred embodiment of the present invention will now be described. FIG. 8 is a plan view showing a pixel in an EL display device according to the third preferred embodiment of the present invention. In this embodiment, a structure is employed in which two S-TFTs 10 and two D-TFTs 20 are provided in each pixel. With this configuration, it is possible to reduce manufacturing variation among D-TFTs 20 by placing a plurality of D-TFTs 20. This configuration is especially advantageous in structures having a wide manufacturing variation among TFTs, or in structures in which a demand for variation reduction is high.

The present invention is not limited to an EL display device and may be applied to other active matrix display devices in which a plurality of transistors are formed on the same substrate for driving and controlling a display element in each pixel. In addition, the present invention is not limited to a display device and may be applied more widely to semiconductor devices formed on a same substrate. For example, it is possible to form, using a common conductive layer, transistors achieving various objects by, for example, placing a conductive direction (channel length direction) of a transistor forming a digital interface or an AC circuit which requires a fast operation or a fast response rate along a direction of a low grain boundary density and a high crystal grain size such as the A direction of FIG. 5, for example, and placing the channel length direction of a transistor having, for example, a high voltage resistance in which the resistive component is increased because the capacity and leak become a problem along a direction of a high grain boundary density such as, for example, the B direction in FIG. 5. Alternatively, it is possible to place transistors of similar characteristics along the same conductive direction to achieve different characteristics by slightly changing the size of the transistors.

### Fourth Embodiment

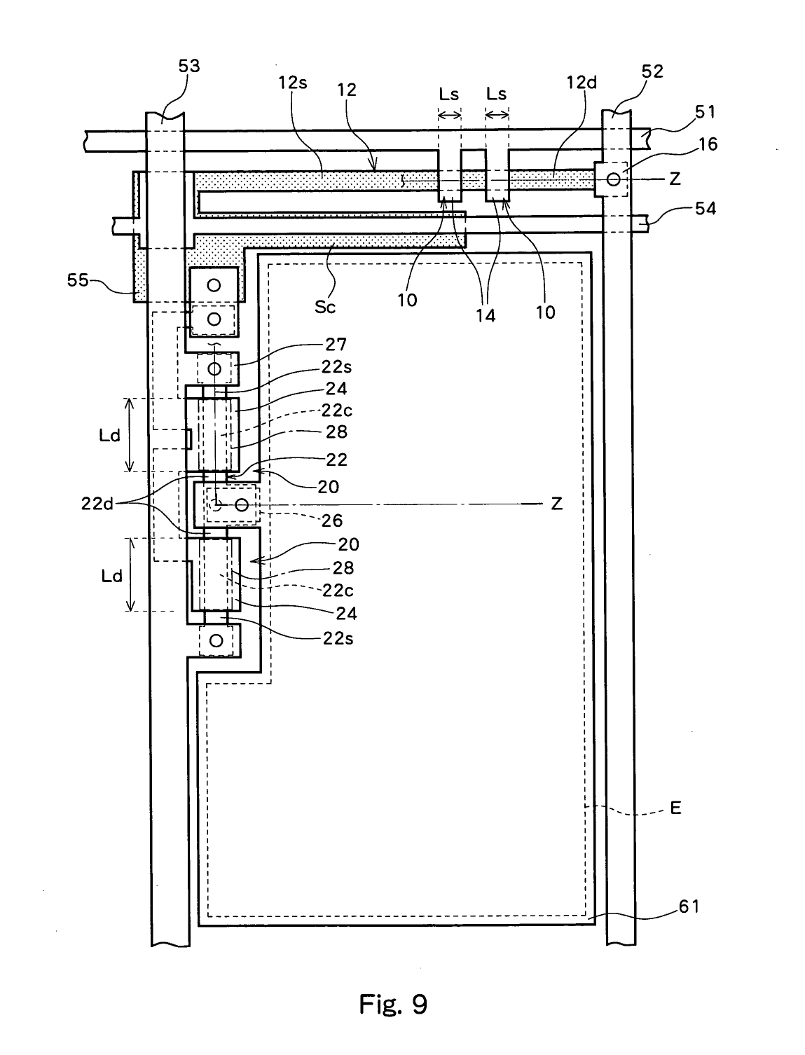

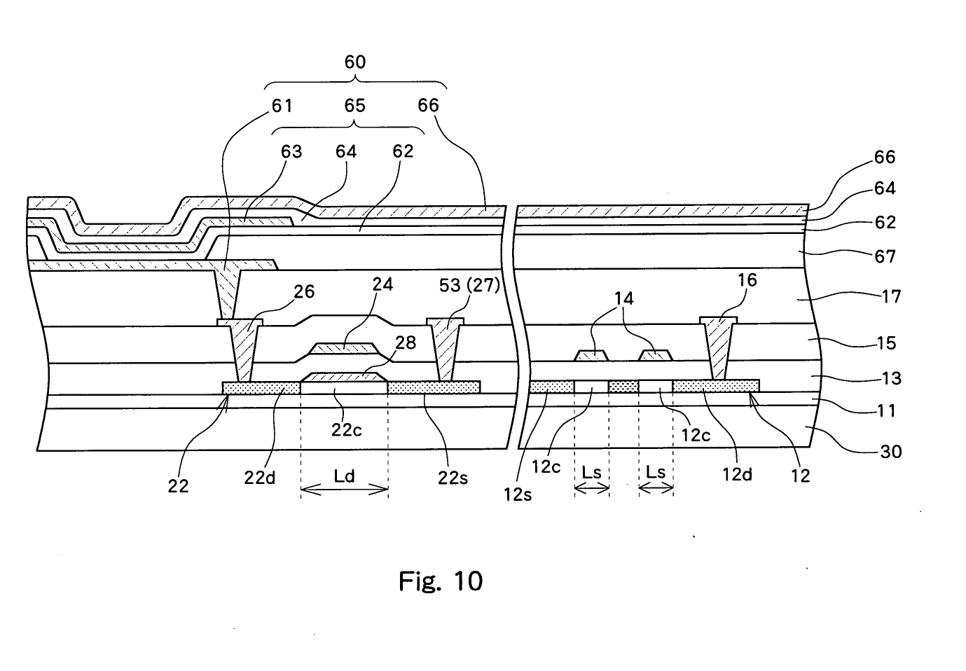

FIG. 9 is a plan view showing a pixel in an EL display device according to a fourth preferred embodiment of the present invention. FIG. 10 is a cross sectional view along the Z-Z line of FIG. 9 and shows a structure of the S-TFT 10 and the D-TFT 20. Layers and structures identical to those in FIGS. 4 and 5 are assigned the same reference numerals and will not be described again.

The present embodiment differs from the embodiments described above in that a cap film 28 made of a SiO₂ film is formed above the channel region 22c of the D-TFT 20. Because the cap film 28 is provided between the channel region 22c and the gate insulating film 13, energy reaching the semiconductor layer of the channel region 22c is reduced in the crystallization step to be described later. Because crystallization in the semiconductor layer of the channel region 22c is inhibited, the crystal grain size in this region becomes smaller than that in the other regions. When the grain size is small, the number of grain boundaries is high, and therefore the mobility is small. In this manner, because it is possible to reduce the mobility in the semiconductor layer of the channel region 22c by reducing the crystal grain size, current supplied from the D-TFT 20 can be reduced.

Moreover, because of the presence of the cap film 28, the thickness of the insulating film between the channel region 22c and the gate electrode 24 is thicker than the thickness of the insulating film between the channel region 12c and the gate electrode 14. When a mobility along the conductive direction of the semiconductor layer of the TFT is A, a channel width of the TFT is W, a channel length of the TFT is L, a thickness of the insulating film from the channel to the gate electrode is d, and a dielectric constant of the insulating film is E, the current I which can be supplied by the TFT can be represented by the following equation (2).
I ∝ μ·(ε/d)·(W/L) (2)

In other words, according to equation (2), the current supplied by the TFT is reduced as the thickness d of the insulating film is increased. Thus, the current I supplied by the D-TFT 20 is reduced by an amount corresponding to the thickness of the cap film 28. Therefore, the cap film 28 reduces the mobility of the semiconductor layer, and, in addition, further reduces the current supply capability by changing the thickness of the insulating film.

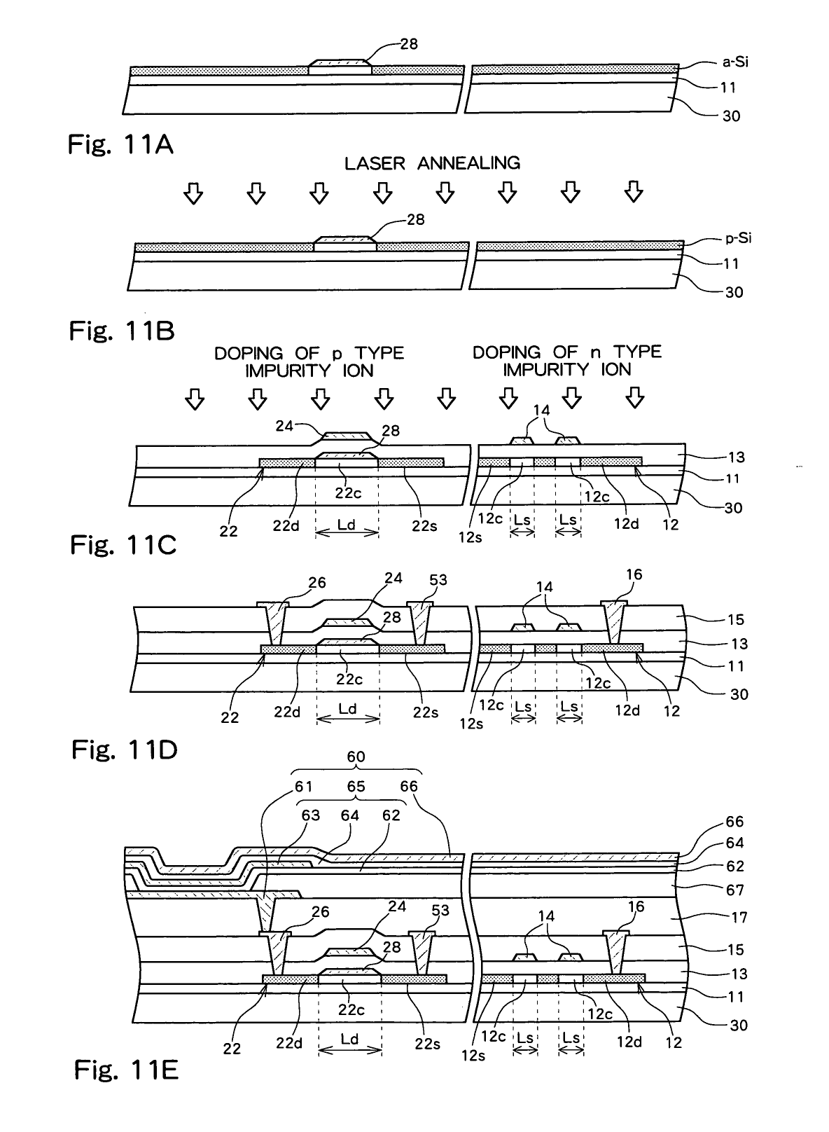

A method of manufacturing an EL display device according to the present invention will now be described referring to FIGS. 11A-11E.

FIG. 11A is a diagram showing a first step. In the first step, an insulating film 11 made of a SiN film and a SiO₂ film is layered on a substrate 30, and an amorphous silicon (a-Si) film is layered over the insulating film 11. Then, a material of a cap film made of an insulating film such as, for example, a SiO₂ film is layered over the a-Si film to a thickness of 80 nm through CVD (Chemical Vapor Deposition), spin coating, or the like. Then, the cap film 28 is patterned through photolithography or the like such that the cap film material is selectively left above the region which will become the channel region of the D-TFT 20 in the later steps. The material of the cap film is not limited to SiO₂ and SiN and may be other insulating films or a combination of these. As compatibility of SiO₂ with the semiconductor layer is superior, it is desirable that a configuration is employed in which at least SiO₂ is in contact with the interface with the semiconductor layer and it is more desirable that a single layer of SiO₂ is employed from the viewpoint of simplifying the manufacturing steps.

FIG. 11B is a diagram showing a second step. In the second step, the entire surface of the a-Si film including the region in which the cap film 28 is formed is uniformly annealed with a laser, such as an excimer laser, to crystallize the a-Si film. During the crystallization, a part of the energy of the excimer laser is absorbed by the cap film 28 in the region in which the cap film 28 is formed. Therefore, laser energy reaching the a-Si film is reduced in the region covered by the cap film 28 (channel region 22c), and, thus, during the crystallization, the crystal grain size of the semiconductor layer of this region becomes smaller than that in the other regions. More specifically, the crystal grain size in the channel region 22c is approximately 0.2 μm and the crystal grain size in the other regions is approximately 0.3 μm-0.4 μm when a beam intensity of the laser is set to approximately 540 mJ during the laser annealing. By increasing the thickness of the cap film 28 or by optimizing the crystallization conditions, it is possible to set the crystal grain size in the semiconductor layer to a microcrystalline level (approximately 0.01 μm-0.05 μm).

FIG. 11C is a diagram showing a third step. In the third step, semiconductor layers 12 and 22 of the S-TFT 10 and the D-TFT 20 are formed by patterning. Then, a gate insulating film 13 made of a SiO₂ film and a SiN film is layered from above the insulating film 11, semiconductor layers 12 and 22, and the cap film 28. Next, a refractory metal such as Cr and Mo is layered above the gate insulating film 13 through sputtering or the like and patterned to cover positions in which the channel regions 12c and 22c are formed, to form the gate electrodes 14 and 24. Using the gate electrode 14 of the S-TFT 10 as a mask, an N type impurity ion such as phosphorus is doped. As a result of this process, the channel region 12c is formed in the region covered by the gate electrode 14 and the source region 12s and the drain region 12d are formed in the regions not covered by the gate electrode 14. Similarly, using the gate electrode 24 of the D-TFT 20 as a mask, a P type ion such as boron is doped. With this process, a channel region 22c is formed in the region covered by the gate electrode 24 and the source region 22s and the drain region 22d are formed in regions not covered by the gate electrode 24. With these steps, a TFT substrate in which TFTs are formed on a substrate is obtained.

FIG. 11D is a diagram showing a fourth step. In the fourth step, an interlayer insulating film 15 made of a SiO₂ film, a SiN film, and a SiO₂ film is layered from above the gate insulating film 13 and the gate electrodes 14 and 24 and contact holes are formed through the interlayer insulating film 15 in regions corresponding to the drain regions 12d and 22d and the source region 22s. A metal such as Al is layered over the entire surface of the interlayer insulating film through these contact holes by sputtering and patterned into a desired shape, to form the drain electrodes 16 and 26 and the source electrode 27.

FIG. 11E is a diagram showing a fifth step. In the fifth step, a planarizing film 17 is layered from above the interlayer insulating film 15, the drain electrodes 16 and 26, and the source electrode 27 and a contact hole is formed through the planarizing film 17 in a region corresponding to the drain electrode 26. A transparent electrode material such as ITO is layered over the entire surface of the planarizing film through the contact hole by sputtering or the like and patterned in a pattern independent for each pixel, to form a pixel electrode 61. Then, a photosensitive organic resin material is layered from above the planarizing film 17 and the pixel electrode 61 through spin coating or the like and is exposed and developed to form a second planarizing film 67 and to form an opening through the second planarizing film 67 in a shape and position corresponding to the emissive region E so that the pixel electrode 61 is exposed in the opening. Next, a hole transport layer 62, an emissive layer 63, and an electron transport layer 64 are evaporated over the entire surface of the substrate above the second planarizing film 67 covering the exposed pixel electrode 61. An opposing electrode 66 is evaporated above the light emitting element layer 65 made of these three layers thus formed.

The method of manufacturing in the present embodiment is not limited to the example described above. For example, the a-Si film may be crystallized after the a-Si film is patterned, and the method can be applied to a bottom-gate type structure in which the semiconductor layers 12 and 14 are formed after the gate electrodes 14 and 24 are formed. In addition, it is also possible to include a dehydrogenation step before the crystallization in order to avoid deficiencies such as abrasion during crystallization.

It is also possible to provide a step of removing the cap film 28 after the crystallization step. In such a case, the gate insulating films of the S-TFT 10 and the D-TFT 20 of the manufactured EL display device comprise the gate insulating film 13 only, resulting in approximately equal dielectric constant. Therefore, the current supplied by the D-TFT 20 is reduced only by a difference in crystal grain sizes, that is, a difference in mobilities, of the non-single crystalline silicon forming the channel regions. This method is particularly useful when the thickness of the cap film cannot be easily controlled, as the method is advantageous in that the control is further simplified because a parameter for controlling the crystal grain size which may become a cause of variation in operation among TFTs can be reduced.

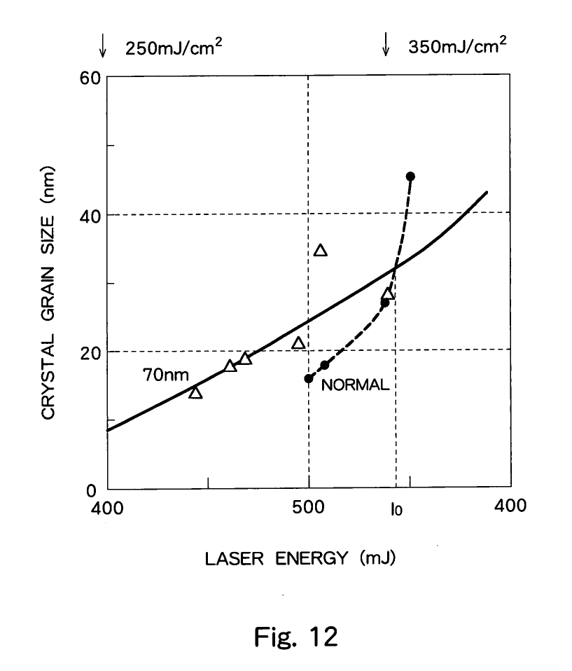

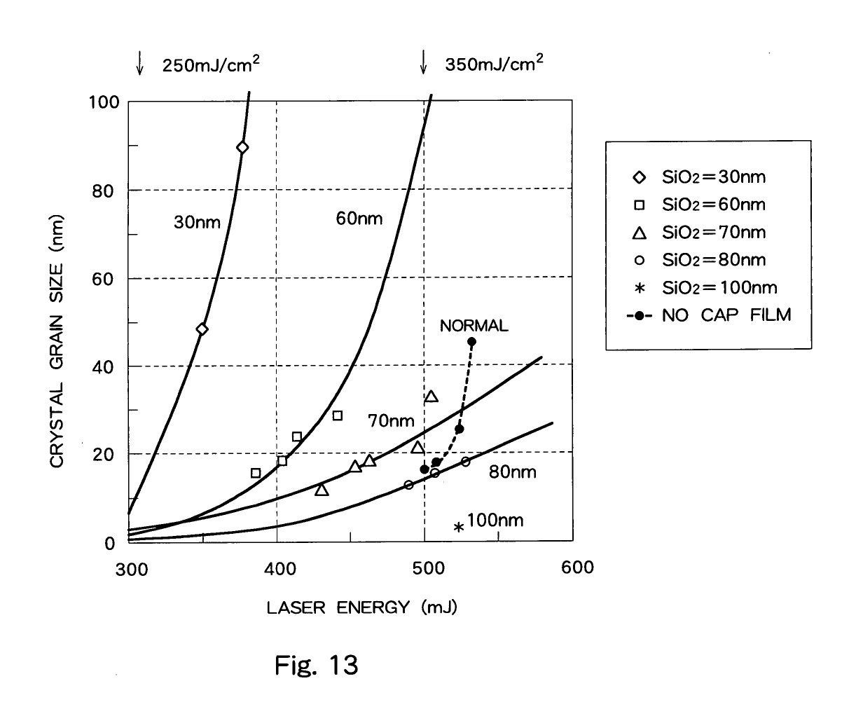

In the present embodiment, it is possible to control the crystal grain size of the semiconductor layer below the cap film by controlling the thickness of the cap film and the energy intensity of the laser. A control of the grain size of the non-single crystalline silicon will now be described referring to FIGS. 12 and 13.

FIG. 12 is a diagram showing relationships between an energy intensity of laser and a crystal grain size of a semiconductor layer for a region in which a cap layer is formed to a thickness of 80 nm and for a region in which the cap film is not formed. From FIG. 12, it can be seen that when the cap film is not formed, the grain size begins to rapidly increase at a certain point when the energy intensity is increased, but, when the cap film 28 is formed, the grain size gradually increases as the energy intensity increases. Thus, it is possible to reduce the grain size in the region in which the cap film is formed with an energy intensity of a certain value (I₀) or greater.

FIG. 13 is a diagram showing a relationship between an energy intensity of laser and a crystal grain size of non-single crystalline silicon when the thickness of the cap film is varied. It can be seen from FIG. 13 that the grain size obtained when laser light of the same energy intensity is irradiated decreases as the thickness of the cap film increases. In the present embodiment, it is necessary to obtain a smaller grain size of non-single crystalline silicon in the channel region in which the cap film is formed compared to the grain size of the non-single crystalline silicon obtained under the normal crystallization conditions which becomes the crystal grain size satisfying the mobility desired for the region in which the cap film is not formed (for example, the S-TFT 10). Therefore, when a laser having a laser intensity of 540 mJ is used, it is preferable to layer and form a cap film having a thickness of 70 nm or greater, and more preferable to layer and form a cap layer of 80 nm or greater, in consideration of various marginal errors. In addition, it is preferable to layer and form a cap film of 100 nm or greater when a semiconductor layer of microcrystalline level of 0.05 μm or greater is to be obtained.

### Fifth Embodiment

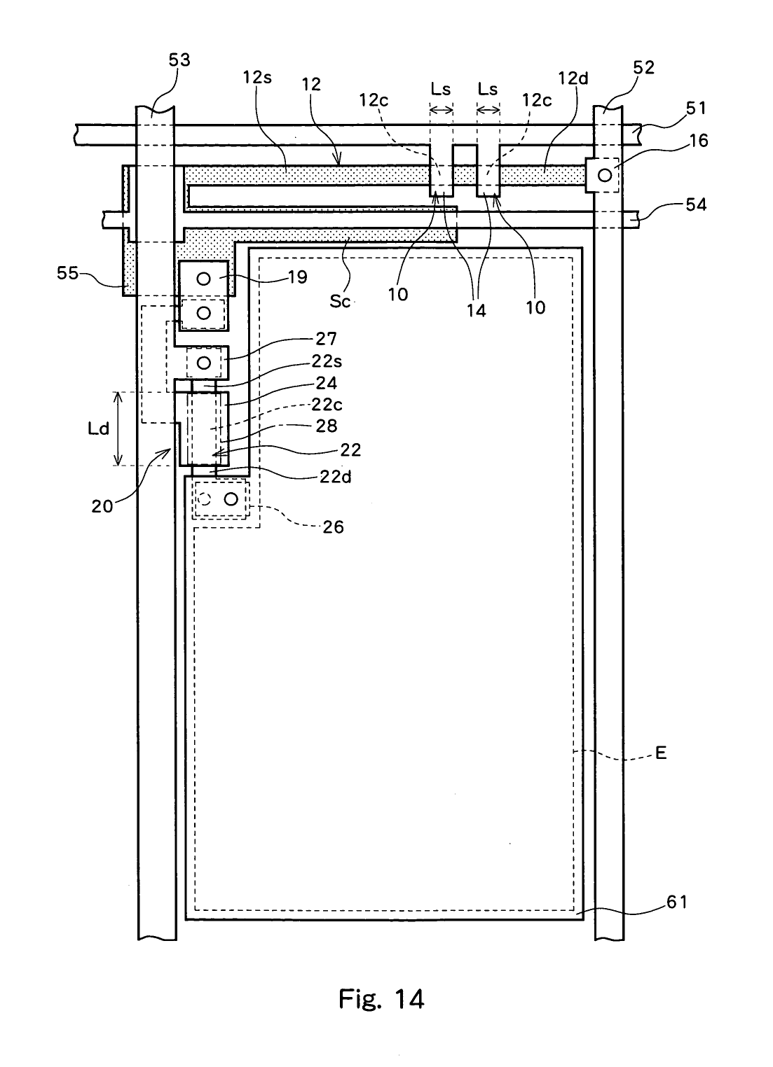

An EL display device according to a fifth preferred embodiment of the present invention will now be described. FIG. 14 is a plan view of a pixel of an EL display device according to the fifth embodiment. In this embodiment, two S-TFTs and a D-TFT 20 are placed within a pixel. With such a structure, because only one D-TFT 20 is provided in each pixel, the aperture ratio can be further improved compared to the first embodiment. In the present embodiment, it is preferable that the channel region 22c of the D-TFT 20 is at a microcrystalline level. Because variation in the crystallinity is less in the case of a microcrystalline level channel region 22c than in a case with a crystal grain size of approximately 300 nm, the variation in the transistor characteristics also is smaller. In consideration of this, the thickness of the cap film 28 is set at 100 nm as described above.

The present invention is not limited to the example structures of the embodiments, and may be realized, for example, by providing a cap film at least above a channel region 22c of the D-TFT 20 and above a channel region 12c of the S-TFT 10. Therefore, the cap film may be formed only over the semiconductor layer 22 of the D-TFT 20 or may be formed also over the other regions.

In the above-described embodiments, EL display devices having two S-TFTs 10 and one D-TFT or two D-TFTs 20 in each pixel are exemplified. The present invention, however, is not limited to these configurations and any number of S-TFTs 10 and D-TFTs 20 may be employed. However, it is desirable that the transistors of the same type are placed with their conductive directions parallel to each other, from the viewpoint of manufacturing variation. In addition, the present invention is not limited to a bottom emission type EL display device in which the light from the emissive layer is output through the TFT substrate to the backside and may be applied to a top emission type EL display device in which the light from the emissive layer is output to the front side of the TFT substrate. The present invention may alternatively be applied to a display device which uses a current-driven light emitting element other than the EL element, or to a display device which requires a plurality of transistors having different functions formed in a pixel region. In the case of a display device requiring three or more transistors having different characteristics, the conductive directions of the transistors may be placed in three or more different directions, and the cap film may be formed with different thicknesses.

1. A semiconductor device comprising:
a first transistor having a first channel region in which a channel length direction extends along a first direction; and
a second transistor formed on a same substrate as the first transistor and having a second channel region in which a channel length direction extends along a second direction which intersects the first direction, wherein
the first channel region and the second channel regions are formed in semiconductor layers which are simultaneously formed, and
a mobility along the first direction and a mobility along the second direction differ from each other in the semiconductor layers.

2. A semiconductor device according to claim 1, wherein
one of two conductive regions of the first transistor is electrically connected to a control electrode of the second transistor, and
the mobility along the first direction is greater than the mobility along the second direction in the semiconductor layers.

3. A semiconductor device according to claim 2, wherein
the first direction is a direction with a maximum mobility within the semiconductor layer, and
the second direction is a direction perpendicular to the first direction.

4. A semiconductor device according to claim 1, wherein
the semiconductor layers used for the channel regions of the first transistor and the second transistor have approximately identical characteristics.

5. A semiconductor device comprising:
a first transistor having a first channel region in which a channel length direction extends along a first direction; and
a second transistor formed on a same substrate as the first transistor and having a second channel region in which a channel length direction extends along a second direction which intersects the first direction, wherein
the first channel region and the second channel region are formed in semiconductor layers which are simultaneously formed, and
a grain boundary density along the first direction and a grain boundary density along the second direction differ from each other in the semiconductor layers.

6. A semiconductor device according to claim 5, wherein
one of two conductive regions of the first transistor is electrically connected to a control electrode of the second transistor, and
the grain boundary density along the first direction is smaller than the grain boundary density along the second direction in the semiconductor layers.

7. A semiconductor device according to claim 6, wherein
the first direction is a direction of minimum grain boundary density within the semiconductor layer, and
the second direction is a direction perpendicular to the first direction.

8. A semiconductor device according to claim 5, wherein
the semiconductor layers used for the channel regions of the first transistor and the second transistors have approximately identical characteristics.

9. A semiconductor device comprising:
a first transistor having a first channel region in which a channel length direction extends along a first direction; and
a second transistor formed on a same substrate as the first transistor and having a second channel region in which a channel length direction extends along a second direction which intersects the first direction, wherein
the first channel region and the second channel region are formed in semiconductor layers which are simultaneously formed, and
an average crystal length along the first direction and an average crystal length along the second direction differ from each other in the semiconductor layers.

10. A semiconductor device according to claim 9, wherein
one of two conductive regions of the first transistor is electrically connected to a control electrode of the second transistor, and
the average crystal length along the first direction is longer than the average crystal length along the second direction in the semiconductor layers.

11. A semiconductor device according to claim 10, wherein
the first direction is a direction of maximum average crystal length within the semiconductor layer, and
the second direction is a direction perpendicular to the first direction.

12. A display device comprising at least one pixel, wherein
each pixel comprises a display element, a first transistor having a first channel region in which a channel length direction extends along a first direction, and a second transistor having a second channel region in which a channel length direction extends along a second direction which intersects the first direction;
the first channel region and the second channel region are formed in semiconductor layers which are simultaneously formed; and
a mobility along the first direction and a mobility along the second direction differ from each other in the semiconductor device.

13. A display device according to claim 12, wherein
the mobility along the first direction is greater than the mobility along the second direction in the semiconductor layers.

14. A display device according to claim 12, wherein
a control electrode of the first transistor is connected to a first signal line;
one of two conductive regions of the first transistor is connected to a second signal line and the other of the two conductive regions of the first transistor is connected to a control electrode of the second transistor;
one of two conductive regions of the second transistor is connected to a third signal line and the other of the two conductive regions of the second transistor is connected to the display element;
the first signal line is formed along a direction which interests an extension direction of the second and third signal lines; and
the first signal line is formed to extend along the first direction.

15. A display device according to claim 14, wherein
the second and third signal lines are formed to extend along the second direction.

16. A display device according to claim 12, wherein
a grain boundary density along the first direction is smaller than a grain boundary density along the second direction in the semiconductor layers.

17. A display device according to claim 12, wherein
an average crystal length along the first direction is longer than an average crystal length along the second direction in the semiconductor layers.

18. A display device comprising at least one pixel, wherein
each pixel comprises a display element, a first transistor having a first channel region in which a channel length direction extends along a first direction, and a second transistor having a second channel region in which a channel length direction extends along a second direction which intersects the first direction;
a control electrode of the first transistor is connected to a first signal line;
one of two conductive regions of the first transistor is connected to a second signal line and the other of the two conductive regions of the first transistor is connected to a control electrode of the second transistor;
one of two conductive regions of the second transistor is connected to a third signal line and the other of the two conductive regions of the second transistor is connected to the display element;
the first channel region and the second channel region are formed in semiconductor layers which are simultaneously formed; and
a grain boundary density along the first direction is smaller than a grain boundary density along the second direction in the semiconductor layers.

19. A display device according to claim 18, wherein
the first direction is a direction of minimum grain boundary density, and
the second direction is a direction perpendicular to the first direction.

20. A display device comprising at least one pixel, wherein:
each pixel comprises a display element, a first transistor having a first channel region in which a channel length direction extends along a first direction, and a second transistor having a second channel region in which a channel length direction extends along a second direction which intersects the first direction;
a control electrode of the first transistor is connected to a first signal line;
one of two conductive regions of the first transistor is connected to a second signal line and the other of the two conductive regions of the first transistor is connected to a control electrode of the second transistor;
one of two conductive regions of the second transistor is connected to a third signal line and the other of the two conductive regions of the second transistor is connected to the display element;
the first channel region and the second channel region are formed in semiconductor layers which are simultaneously formed; and
an average crystal length along the first direction is longer than an average crystal length along the second direction in the semiconductor layers.

21. A display device according to claim 20, wherein
the first direction is a direction of maximum average crystal length, and
the second direction is a direction perpendicular to the first direction.

22. A display device according to claim 20, wherein
the display element is an electroluminescence element.

23. A semiconductor device comprising a first transistor and a second transistor on a same substrate, wherein
a common insulating film is formed over a first channel region and a second channel region;
a cap film is provided between the insulating film and a channel region of the second transistor; and
a crystal grain size of a semiconductor layer forming a channel region of the first transistor and a crystal grain size of a semiconductor layer forming the channel region of the second transistor differ from each other.

24. A semiconductor device according to claim 23, wherein
a thickness of the cap film is 80 nm or greater.

25. A semiconductor device according to claim 23, wherein
a thickness of the cap film is 100 nm or greater.

26. A semiconductor device according to claim 23, wherein
the cap film contains a silicon oxide.

27. A semiconductor device according to claim 23, wherein
a channel length direction of the first transistor is identical to a channel length direction of the second transistor, and
a mobility along the channel length direction of the first transistor and a mobility along the channel length direction of the second transistor differ from each other.

28. A display device comprising at least one pixel, wherein
each pixel comprises at least a pixel electrode, a first transistor, and a second transistor;
one of two conductive regions of the first transistor is connected to a control electrode of the second transistor;
the second transistor supplies a signal corresponding to an output of the first transistor to the pixel electrode;
a channel region of the first transistor and a channel region of the second transistor are formed using a same semiconductor material;
a common insulating film is formed over a first channel region and a second channel region;
a cap film is provided between the insulating film and the channel region of the second transistor; and
a crystal grain size of a semiconductor layer forming a channel region of the first transistor and a crystal grain size of a semiconductor layer forming the channel region of the second transistor differ from each other.

29. A display device according to claim 28, wherein
a channel length direction of the first transistor is identical to a channel length direction of the second transistor, and
a mobility along the channel length direction of the first transistor and a mobility along the channel length direction of the second transistor differ from each other.

30. A display device according to claim 28, wherein
a thickness of the cap film is 80 nm or greater.

31. A display device according to claim 28, wherein
a thickness of the cap film is 100 nm or greater.

32. A display device according to claim 28, wherein
the cap film contains a silicon oxide.

33. A method of manufacturing a display device comprising at least one pixel, each pixel comprising a first transistor, a second transistor, and a pixel electrode wherein power is supplied through the second transistor to the pixel electrode according to an output from the first transistor, the method comprising the steps of:
forming an amorphous silicon film above a substrate;
forming a cap film covering a channel formation region of the second transistor above the amorphous silicon film; and
crystallizing the amorphous silicon film by applying a laser annealing process to the amorphous silicon film while the channel formation region of the second transistor is covered with the cap film and a surface of the amorphous silicon film is exposed in a channel formation region of the first transistor.

34. A method of manufacturing a display device according to claim 33, wherein
polycrystalline silicon films having different crystal grain sizes are formed in a channel region of the first transistor and in a channel region of the second transistor through the laser annealing process.

35. A method of manufacturing a display device according to claim 34, wherein
the first transistor and the second transistor are formed such that channel length directions of the first and second transistors extend in an identical direction; and
an average crystal grain size along the channel length direction of the channel region of the second transistor is smaller than an average crystal grain size along the channel length direction of the channel region of the first transistor.

36. A method of manufacturing a display device according to claim 34, wherein
the laser annealing process is executed by irradiating the amorphous silicon film with a laser beam via the cap film in the channel formation region of the second transistor and by directly irradiating the amorphous silicon film with the laser beam in the channel formation region of the first transistor.

37. A method of manufacturing a display device according to claim 34, wherein
after the laser annealing process, the cap film is removed and an insulating film is formed covering the obtained polycrystalline silicon film.

38. A method of manufacturing a display device according to claim 34, wherein
the cap film is made of a silicon oxide.

39. A method of manufacturing a display device according to claim 34, wherein
after the laser annealing process, a common gate insulating film is formed directly covering the obtained polycrystalline silicon film in the channel formation region of the first transistor and covering the cap film formed above the obtained polycrystalline silicon film in the channel formation region of the second transistor.

40. A method of manufacturing a semiconductor device having a first transistor and a second transistor, comprising the steps of:
forming an amorphous silicon film above a substrate;
forming a cap film covering a channel formation region of the second transistor above the amorphous silicon film; and
crystallizing the amorphous silicon film by applying a laser annealing process to the amorphous silicon film while in a state in which the channel formation region of the second transistor is covered with the cap film and a surface of the amorphous silicon film is exposed in a channel formation region of the first transistor.

41. A method of manufacturing a semiconductor device according to claim 40, wherein
the cap film is removed after the laser annealing process.

42. A method of manufacturing a semiconductor device according to claim 40, wherein
the cap film is made of a silicon oxide.
